(19) United States
(12) Patent Application Publication
(10) Pub. No.: US 2001/0050935 A1
(43) Pub. Date: Dec. 13, 2001

(54) Surface emitting semiconductor laser device

(76) Inventor: Noriyuki Yokouchi, Tokyo (JP)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/851,751

(22) Filed: May 9, 2001

(30) Foreign Application Priority Data
May 24, 2000 (JP) 2000-153125

(51) Int. Cl. H01S 5/00

(52) U.S. Cl. 372/45

(57) ABSTRACT

A surface emitting semiconductor laser device comprising: a layered structure in which a light-emitting layer is disposed between a pair of reflector layered structures formed by hetero junction of a plurality of semiconductor materials, the layered structure being formed on a substrate and an impurity being doped into the reflector layered structure; wherein in the reflector layered structure the doping concentration of said impurity into a region positioned in the vicinity of the light-emitting layer is relatively smaller than the doping concentration of said impurity into other regions spaced from the light-emitting layer; and at the same time, in the reflector layered structure the region positioned in the vicinity of said light-emitting layer has a relatively smaller energy gap difference ΔEg between the semiconductor materials forming the region than the energy gap difference ΔEg between the semiconductor materials forming the other regions, and the driving voltage can be reduced without the deterioration of the optical output power characteristics.

### BACKGROUND OF THE INVENTION

1. Field of the Invention

The present invention relates to a surface emitting semiconductor device, and more specifically relates to a surface emitting semiconductor device, which can reduce the driving voltage without deterioration of the optical output power characteristics.

2. Prior Art

Recently, a study to realize the construction of large-capacity optical communication network or the construction of optical data communication systems such as an optical interconnection system, an optical computing system and the like has been advanced, and, as these light sources, attention is being given to surface emitting semiconductor laser devices.

One example of such surface emitting semiconductor laser devices is shown in FIG. 1.

In this device, a lower reflector layered structure 2 is first formed on a substrate comprised of, for example, n type GaAs.

This lower reflector layered structure 2 is so-called a DBR (Distributed Bragg's Reflector) multi-layered film, which is formed by alternately laminating paired layers in which two semiconductor materials having different compositions from each other and thus having different indexes of refraction are connected to each other by hetero-junction to form a pair of layers and a plurality of the pairs of layers are alternately laminated.

On this lower reflector layered structure 2 are sequentially laminated, a lower cladding layer 3a comprised of, for example, non-doped AlGaAs, a light-emitting layer 4 of a quantum well structure comprised of GaAs/AlGaAs, and an upper cladding layer 3b comprised of non-doped AlGaAs. Further, on the upper cladding layer 3b, a DBR multi-layered structure formed by alternate hetero junctions of semiconductor materials having different compositions, that is, indexes of refraction, and on the surface of the uppermost layer of this upper reflector layered structure 5 a p-type GaAs layer (cap layer) 6 is formed, thereby forming an entire layered structure. Further, a peripheral portion of the layered structure or the portion extending to the top of at least the lower reflector layered structure 2 is etched so that a column layered structure is formed at the center of the structure.

An annular top electrode 7a made of, for example, AuZn is formed in the vicinity of the peripheral portion of the upper surface of the cap layer 6 in the column layered structure positioned at the center. Also a bottom electrode 7b made of, for example, AuGeNi/Au is formed on the back of the substrate 1.

Of all surfaces of the structure a side surface 5a of the column portion and a peripheral portion 6b positioned outside the top electrode 7a of the surfaces of the cap layer 6 are covered with a dielectric film 8 made of, for example, silicon nitride (for example, Si₃N₄), so that the center surface of the cap layer 6, that is, the inside portion 6a of the top electrode 7a is formed as a laser beam emission window. Further, the surfaces of the top electrode 7a and the dielectric film 8 are covered to form a metallic film pad 9 for leading the top electrode 7a made of, for example, Ti/Pt/Au.

Further, in this laser device, the lowest layer of the upper reflector layered structure 5, that is, the layer 5a positioned at a place nearest the light-emitting layer 4 is made of, for example, p-type AlAs.

The outside portion of the above-described layer 5a is an insulating region 5b mainly formed of Al₂O₃ having an annular shape in a plan view. This insulating region 5b is formed by selectively oxidizing the outside portion of AlAs forming the layer 5a.

The center portion of the layer 5a is a current injection path 5c formed of non-oxidized AlAs so that a current blocking structure for the light-emitting layer 4 is formed as a whole.

In this laser device, by applying voltage to the top go electrode 7a and the bottom electrode 7b the light emission at the light-emitting layer 4 is excited between the above-described pair of reflector layered structures 2 and 5 to generate laser oscillation, and the laser beam is passed through the cap layer 6 and oscillated from the surface portion 6a (the emission window of the laser beam) as shown by an arrow, that is, upward vertically with respect to the substrate 1.

Since any of the reflector layered structures described above is a layered structure formed by alternate hetero junctions of semiconductor materials having different indexes of refraction from each other (having different compositions), the electric resistance is generally high in a direction of the layer thickness. Thus, when an driving current, which is supplied for the purpose of the oscillation of high optical output power, is increased, the resistance heat is also increased, so that the optical output power of the device is remarkably decreased. For this reason, it is preferable to make a reflector layered structure having a low resistance.

A method of realizing a reflector layered structure having a low resistance is known in the following method.

That is, one method is that an impurity such as carbon (C) is doped at a high concentration in the vicinity of a hetero junction interface in a semiconductor layer having a wider energy band gap of semiconductor material layers connected by hetero junction adjacent to each other in a direction of the layer thickness. This method has already been implemented.

However, when the impurity doping concentration in a region positioned in the vicinity of the light-emitting layer in the reflector layered structure, is increased, the light absorption in the region becomes significant. As a result, a problem occurs in that the optical output power characteristics of the device will be deteriorated.

As explained above, when impurities are doped at a high concentration into the region positioned in the vicinity of the light-emitting layer in the reflector layered structure, a low-resistance reflector layered structure can be realized. In such a case, however, the optical output power characteristics of the device will be deteriorated. On the contrary, when the doping concentration of impurities is decreased to suppress the deterioration of the optical output power characteristics, a problem arises in that the reflector layered structure exhibits high resistance and the driving current cannot be reduced.

### OBJECT AND SUMMARY OF THE INVENTION

The object of the present invention is to solve the above-described problems that conventionally occurred at the time of doping of impurities to the reflector layered structure, and to provide a new surface emitting semiconductor laser device which can make a reflector layered structure exhibit low resistance without causing the deterioration of optical output power characteristics of the laser device.

To attain the above-mentioned object the present invention provides a surface emitting semiconductor laser device comprising:

a layered structure in which a light-emitting layer is disposed between a pair of reflector layered structures formed by hetero junction of a plurality of semiconductor materials, said layered structure being formed on a substrate and an impurity being doped into said reflector layered structure;

wherein in said reflector layered structure the doping concentration of said impurity into a region positioned in the vicinity of said light-emitting layer is relatively smaller than the doping concentration of said impurity into other regions; and at the same time, in said reflector layered structure said region positioned in the vicinity of said light-emitting layer has a relatively smaller energy gap difference between the semiconductor materials forming said region than the energy gap difference between the semiconductor materials forming said other regions.

### BRIEF DESCRIPTION OF THE DRAWINGS

FIG. 1 is a cross-sectional view showing a layered structure of a surface emitting semiconductor laser device;

FIG. 2 is a schematic view showing one example of a surface emitting semiconductor laser device according to the present invention;

FIG. 3 is a schematic view showing a state of the impurity doping concentration in the layered structure of FIG. 2;

FIG. 4 is a graph showing current-voltage characteristics;

FIG. 5 is a graph showing current-optical output power characteristics; and

FIG. 6 is a graph showing the result of a current-carrying test of a device.

### DETAILED DESCRIPTION OF THE INVENTION

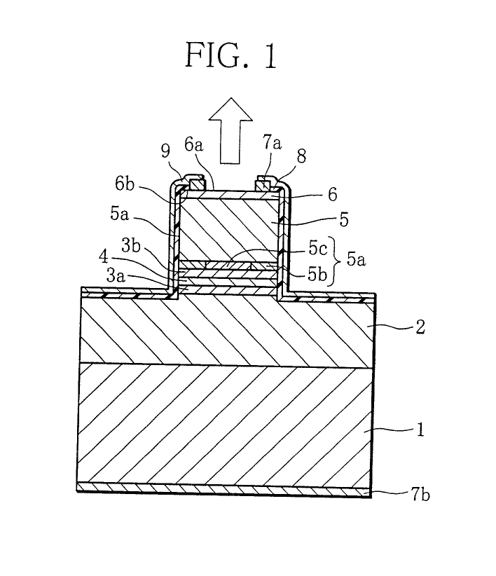

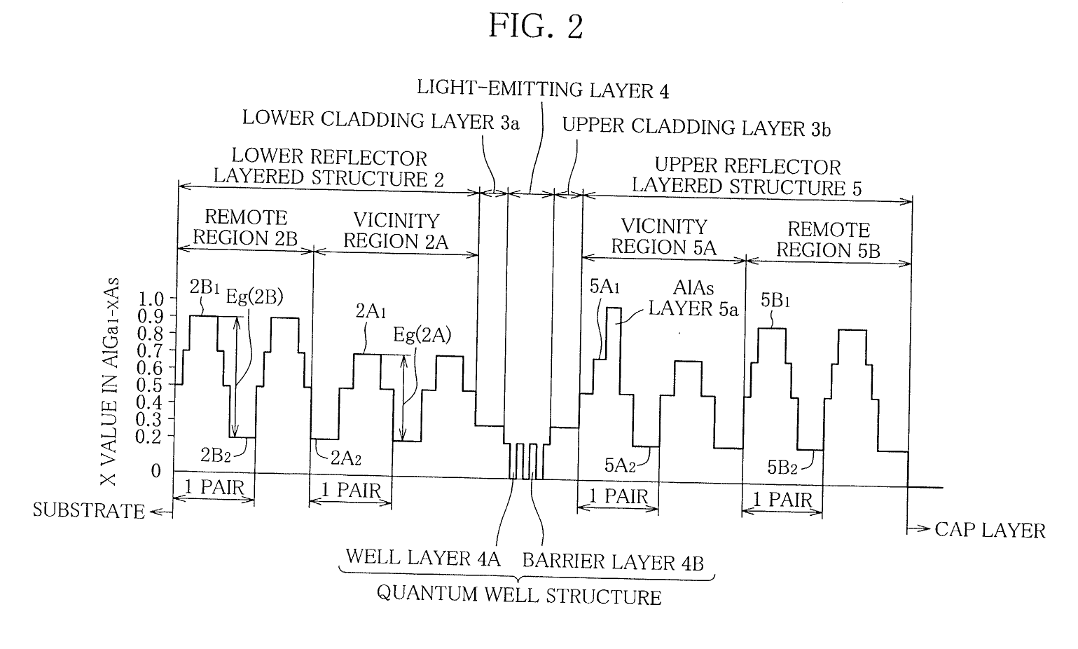

A detailed one example of a laser device according to the present invention, wherein the entire layered structure is basically the same as that shown in FIG. 1 and an n-type GaAs substrate is used as the substrate and AlₓGaₗ₋ₓAs (0≦×≦1) is used as a semiconductor material, is shown in FIG. 2.

In FIG. 2, the horizontal axis represents the types of layered structures formed between the n-type GaAs substrate 1 and the p-type GaAs cap layer 6, and the vertical axis represents the composition of the semiconductor materials forming the respective semiconductor layers, and the degree between the energy gaps in each layer.

In this laser device, on the n-type GaAs substrate 1 an n-type lower reflector layered structure 2, an n-type lower cladding layer 3a, a non-doped light-emitting layer 4 comprised of a well layer 4A and a barrier layer 4B, and having three quantum wells, a p-type upper cladding layer 3b, and a p-type upper reflector layered structure 5 are sequentially laminated. The above-described light-emitting layer 4 is disposed between the pair of reflector layered structures 2 and 5. Further, a cap layer 6 formed of p-type GaAs is formed on the reflector layered structure 5.

In the present invention, in the above-described layered structures, the lower reflector layered structure 2 and the upper reflector layered structure 5 each have a region positioned in the vicinity of the light-emitting layer (hereinafter referred to as a vicinity region) and a region positioned outside the vicinity region (a remote region).

Here, The remote regions 2B (5B) in the lower and upper reflector layered structures 2 and 5 each have a layered structure in which a plurality of paired layers formed by the hetero junction of a wide energy band gap layer 2B₁ (5B₁) formed of Al_{0.9}Ga_{0.1}As and a narrow energy band gap layer 2B₂ (5B₂) formed of Al_{0.2}Ga_{0.8}As. Between the layer 2B₁ (5B₁) and 2B₂ (5B₂) two quasi-composition-graded layers using Al_{0.7}Ga_{0.3}As and Al_{0.5}Ga_{0.5}As are inserted, as shown by the two steps in FIG. 2.

The vicinity region 2A of the lower reflector layered structure 2 has a layered structure in which a plurality of paired layers formed by the hetero junction of a narrow energy band gap layer 2A₂ formed of Al_{0.2}Ga_{0.8}As and a wide band gap layer 2A₁ formed of Al_{0.7}Ga_{0.3}As. Between the respective layers, one layer of Al_{0.5}Ga_{0.5}As is respectively inserted as a composition-graded layer.

Also, the vicinity region 5A of the upper reflector layered-structure 5 has a layered structure in which a plurality of paired layers formed by the hetero junction of a wide band gap layer 5A₁ formed of Al_{0.7}Ga_{0.3}As and a narrow energy band gap layer 5A₂ formed of Al_{0.2}Ga_{0.8}As. Between the respective layers, one layer of Al_{0.5}Ga_{0.5}As is respectively inserted as a composition-graded layer. However, in the case of the layer 5A₁ which is positioned just above the upper cladding layer 3b in this vicinity region 5A, the lowest layer is an AlAs layer 5a that can form a current-blocking structure mentioned above.

It is noted that in the layered structure of FIG. 2, the light-emitting layer 4 disposed between the lower reflector layered structure 2 and the upper reflector layered structure 5 has a quantum well structure comprised of a well layer 4A of non-doped GaAs and a barrier layer 4B of non-doped Al_{0.2}Ga_{0.8}As, and the upper cladding layer 3b and the lower cladding layer 3a each formed of non-doped Al_{0.3}Ga_{0.7}As are disposed on and below this light-emitting layer 4.

In the case of the laser device of the present invention, the above-described layered structure has the following features.

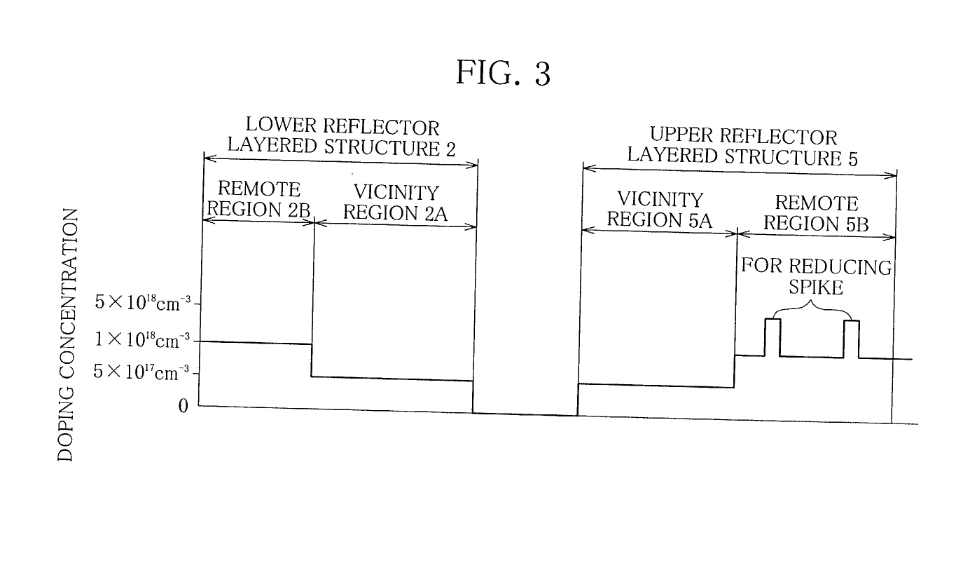

(1) First, in the individual reflector layered structure the impurity doping concentration in the vicinity region is relatively lower than the impurity doping concentration in the remote region. One example of the structure is shown in FIG. 3.

In the case of FIG. 3, in the remote region 2B of the lower refractive layered structure 2, n-type impurities such as silicon (Si) or the like are doped into the respective semiconductor layers, and the concentration in the region amounts to 1×10¹⁸ cm⁻³. Further, in the vicinity region 2A positioned above the remote region 2B, the doping concentration of n-type impurities amounts to 5×10¹⁷ cm⁻³.

Also, in the case of the upper reflector layered structure 5, p-type impurities such as carbon (C) or the like are doped into the vicinity region 5A, and the concentration of the doped impurities amounts to 5×10¹⁷ cm⁻³. Further, in the remote region 5B positioned thereon a p-type impurity doping concentration is set to 1×10¹⁸ cm⁻³. The peaks of high concentration in the remote region 5B are provided for reducing a spike.

Here, the vicinity region 2A (5A) has the pair number of 2 to 5, each pair being formed by the hetero junction as mentioned above, and it is preferable that the entire doping into each pair be performed at a low concentration. This reason is that when this vicinity region 2A (5A) is formed by too many pairs, the reflector layered structure exhibits a high resistance and the deterioration the optical output power characteristics is commenced by heat generation.

Further, in any of the remote region and the vicinity region, too high doping concentration produces a reflector layered structure of low resistance. On the other hand, the higher doping concentration leads to a function loss as the reflector layered structure of a DBR multi-layered film. Accordingly, it is preferable that the doping concentrations in the remote region and the vicinity region are suppressed to about 0.5-5×10¹⁸ cm⁻³ and 1-5×10¹⁷ cm⁻³, respectively.

(2) Another feature is that as shown in FIG. 2, the energy gap difference ΔEg (2A, 5A) between the layer 2A₁ (5A₁) forming the vicinity region 2A (5A) and the layer 2A₂ (5A₂) is relatively smaller than the energy gap difference ΔEg (2B, 5B) between the layer 2B₁ (5B₁) forming the remote region 2B (5B) and the layer 2B₂ (5B₂).

When attention is given to the energy of Γ point which controls the electrical conduction characteristics, the above-described ΔEg (2B, 5B) and ΔEg (2A, 5A) are set to 1 eV and 0.7 eV, respectively, and it is preferable that the difference therebetween be set to at least 0.2 eV or more.

The reason is that by the doping reduction in the vicinity region an increase in the driving voltage of about 0.2 V is generated and an increased in the driving voltage can be cancelled if the energy difference between ΔEg (2B, 5B) and ΔEg (2A, 5A) is set to 0.2 eV or more.

It is noted that the control of these energy gap differences can be conducted by appropriately designing the composition of the semiconductor materials used in forming the layered structure.

In the foregoing description, GaAs is taken as an example of the semiconductor material forming the light-emitting layer, but GaInNAs may alternatively be used for the purpose, in which case the resulting laser device has a lasing wavelength band of 1300 nm.

Also, the upper and lower reflector layered structures may be formed using GaInAsP, instead of AlGaAs.

### EXAMPLES

1. Production of Laser Device

The laser device of the layered structure shown in FIGS. 2 and 3 was produced by the following steps.

First, by an MOCVD process 30.5 paired layers, one pair layer (thickness: 111 nm) of which was formed by the hetero junction of Al_{0.9}Ga_{0.1}As (thickness: 48 nm) and Al_{0.2}Ga_{0.8}As (thickness: 43 nm), were laminated on the n-type GaAs substrate 1, and at the same time the remote region 2B having the doped concentration of 1×10¹⁸ cm⁻³ was formed using Si as the n-type impurity. Further, on the obtained structure 5.5 paired layers, one pair layer (thickness: 109 nm) of which was formed by the hetero junction of Al_{0.7}Ga_{0.3}As (thickness: 46 nm) and Al_{0.2}Ga_{0.8}As (thickness: 43 nm), were laminated, and at the same time the remote region 2A having the doped concentration of 5×10¹⁷ cm⁻³ was formed using Si as the n-type impurity so that the lower reflector layered structure 2 was formed.

It is noted that in the layered structure, the above-mentioned energy gap difference ΔEg (2B) in the remote region 2B is 1.06 eV, and the above-mentioned energy gap difference ΔEg (2A) in the vicinity region 2A is 0.65 eV.

Then, on the lower reflector layered structure 2 the lower cladding layer 3a (thickness: 93 nm) formed of non-doped Al_{0.3}Ga_{0.7}As, the light-emitting layer 4 comprised of a quantum well structure of three-layered non-doped Ga As well layer 4A (thickness of each layer: 7 nm) and a four-layered non-doped Al_{0.2}Ga_{0.8}As barrier layer 4B (thickness of each layer: 10 nm), and the upper cladding layer 3b (thickness: 93 nm) formed of non-doped Al_{0.3}Ga_{0.7}As were sequentially formed.

Then, on the upper cladding layer 3b, 5 paired layers, one pair layer (thickness: 109 nm) of which was formed by the hetero junction of Al_{0.7}Ga_{0.3}As (thickness: 46 nm) and Al_{0.2}Ga_{0.8}As (thickness: 43 nm), were laminated, and at the same time the vicinity region 5A having the doped concentration of 5×10¹⁷ cm⁻³ was formed using C as the p-type impurity. Further, on the obtained structure, 20 paired layers, one pair layer (thickness: 111 nm) of which was formed by the hetero junction of Al_{0.9}Ga_{0.1}As (thickness: 48 nm) and Al_{0.1}Ga_{0.8}As (thickness: 43 nm), were laminated, and at the same time the remote region 5B having the doped concentration of 1×10¹⁸ cm⁻³ was formed using C as the p-type impurity so that the upper reflector layered structure 5 was formed.

It is noted that the lowest layer in the vicinity region 5A was formed of 20 nm thick AlAs layer 5a. Further, in the case of this layered structure, the energy gap difference ΔEg (5B) between the hetero junction layers in the remote region 5B is 1.06 eV, and the energy gap difference ΔEg (5A) between the hetero junction layers in the vicinity region 5A is 0.65 eV.

Further, between the layer 2B₁ (5B₁) and the layer 2B₂ (5B₂) in the remote region 2B (5B), two quasi-composition-graded layers of a 10 nm thick Al_{0.7}Ga_{0.3}As layer and a 10 nm thick Al_{0.5}Ga_{0.5}As layer were inserted, and between the layer 2A₁ (5A₁) and the layer 2A₂ (5A₂) in the vicinity region 2A (5A), a 20 nm thick Al_{0.5}Ga_{0.5}As layer was inserted as a composition-graded layer.

Then, on the upper reflector layered structure 5, a 20 nm thick p-type GaAs layer was formed using C as the p-type impurity as the cap layer 6.

After that, an Si₃N₄ thin film was formed by a plasma CVD process on the cap layer 6 of the above-described layer structure, and a circular resist pattern having a diameter of about 45 μm was formed on the obtained structure by a photolithography process using a usual photoresist.

Then, after all Si₃N₄ thin films other than the Si₃N₄ thin film just below the above-mentioned resist pattern were etched off by an RIE process using CF₄, wet etching using a mixed solution of phosphoric acid, an aqueous hydrogen peroxide and water, was performed using the residual Si₃N₄ thin film as a mask to form a column structure whose base extends to the lower reflector layered structure 2.

After that, the obtained entire structure was heated at a temperature of 400° C. for about 25 minutes in a vaporized water atmosphere. As a result, only the outside of the p-type AlAs layer 5a was selectively oxidized in an annular shape so that a current injection path 5c having a diameter of about 15 μm was formed at the center of the annular structure (FIG. 1).

Subsequently, after the Si₃N₄ thin films were completely removed by an RIE process, the entire surface of the structure was newly covered with an Si₃N₄ thin film 8 by a plasma CVD process, and subsequently, the center portion of the Si₃N₄ thin film 8 formed on the top of the cap layer 6 having a diameter of about 45 μm was removed in a circular shape to expose the surface of the cap layer 6.

After that, an annular top electrode 7a having an outer diameter of 25 μm and an inner diameter of 15 μm was formed with AuZn and a Ti/Pt/Au film 9 which functions as a lead pad of electrode was formed on the entire surface of the obtained structure.

Then, after the back of the substrate 1 was polished to make the entire thickness of the substrate 1 about 100 μm, AuGeNi/Au was evaporated on the polished surface of the substrate 1 to form the bottom electrode 7b. As a result, a device having a layered structure shown in FIG. 1 was produced.

The thus obtained device is defined as an example device.

For the purpose of comparison, a laser device having the same layered structure as the example device was produced except that the lower reflector layered structure was formed by laminating 35.5 paired layers, one pair structure being formed by hetero junction of Al_{0.9}Ga_{0.1}As and Al_{0.2}Ga_{0.8}As, and by doping Si into the entire structure, the doping concentration being uniform at 1×10¹⁸ cm⁻³, and the upper reflector layered structure was formed by laminating 25 paired layers, one pair structure being formed by hetero junction of Al_{0.9}Ga_{0.1}As and Al_{0.2}Ga_{0.8}As, and by doping C into the entire structure, the doping concentration being uniform at 1×10¹⁸ cm⁻³. The thus obtained laser device is designated as a comparative example device 1.

In comparison between the example device and this comparative example device 1, the vicinity region and/or the remote region according to the present invention are/is not formed in the comparative example device 1.

Further, as another comparative example, a laser device having the same compositions of the semiconductor materials forming the upper and lower reflector layered structures as in the comparative example device 1 except that the C doping concentration at 5.5 paired structure in the vicinity of the light-emitting layer was set to 5×10¹⁷ cm⁻³, and the C doping concentration to other doping regions was set to 1×10¹⁸ cm⁻³, was produced. The thus obtained device is designated as a comparative example device 2.

This comparative example device 2 forms the difference in the doping concentrations between a region positioned in the vicinity of the light-emitting layer and a region spaced therefrom, but it has the same energy gap difference between the layers of the hetero junction in the above-mentioned both regions.

Furthermore, as another comparative example, a laser device having the same compositions of the semiconductor materials forming the upper and lower reflector layered structures as in the example device except that the doping concentrations were constantly set to 1×10¹⁸ cm⁻³ at all regions, was produced. The thus obtained device is designated as a comparative example device 3.

In comparison between the example device and the comparative example device 3, the layered structures of both devices are the same in the composition, and the energy gap difference between the layers in the regions positioned in the vicinity of the light-emitting layer is smaller than the energy gap difference between the layers in the regions spaced from the light-emitting layer. However, in the case of the comparative example device 3, there is no difference in the doping concentration.

2. Characteristics of Laser Devices

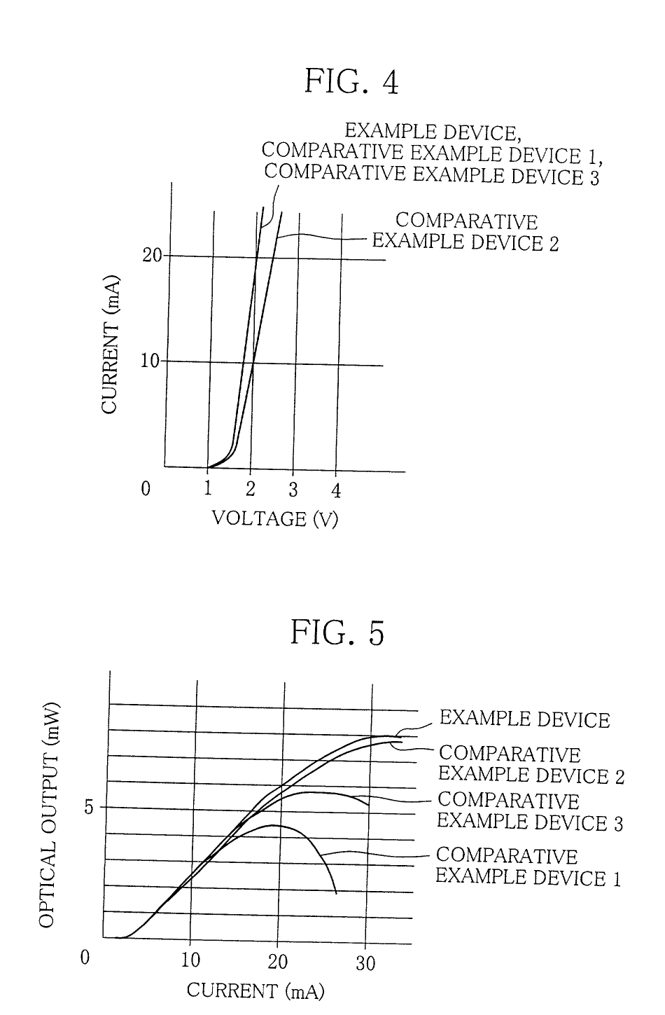

The voltage-current characteristics, and current-optical output power characteristics of the above-described four types of lasers are shown in FIGS. 4 and 5, respectively.

The following characteristics are apparent from FIGS. 4 and 5.

(1) First, in the example device of the present invention, the doping concentration in the vicinity region to the light-emitting layer is low. However, an increase in the driving voltage is not recognized. On the contrary, in the case of the comparative example device 2 in which only the doping concentration in the vicinity region was decreased, the driving voltage was increased by about 0.3 V, which leads to higher resistance as compared with the case of the example device.

(2) In FIG. 5, if attention is given to the optical output power, no saturation of the optical output power is recognized until the driving current becomes 30 mA in both example device and comparative example device 2. On the contrary, in the case of the comparative example device 1 which has no doping concentration difference between the vicinity region and the remote region from the light-emitting layer, when the driving current becomes 20 mA, the saturation of the optical output power can be recognized.

This result indicates that when the doping concentration in the vicinity region to the light-emitting layer is decreased, the optical absorption at the region is suppressed.

(3) Further, although, in the case of comparative example device 3, the doping concentration in the vicinity region to the light-emitting layer is not decreased, the optical output power level is further increased than in the case of comparative example device 1. It is considered that this reason is derived from the facts that since in the case of the comparative example device 3, the energy gap difference between the respective semiconductor layers in the vicinity region to the light-emitting layer is smaller than the energy gap difference between the respective semiconductor layers in the remote region from the light-emitting layer, the refractive index difference between both regions becomes small, so that the evanscene of light often occurs, and therefore, the light intensity in the vicinity region to the light-emitting layer is reduced, and that even if the light absorption based on the impurity doping is increased heat generation is further suppressed than in the case of comparative example device 1.

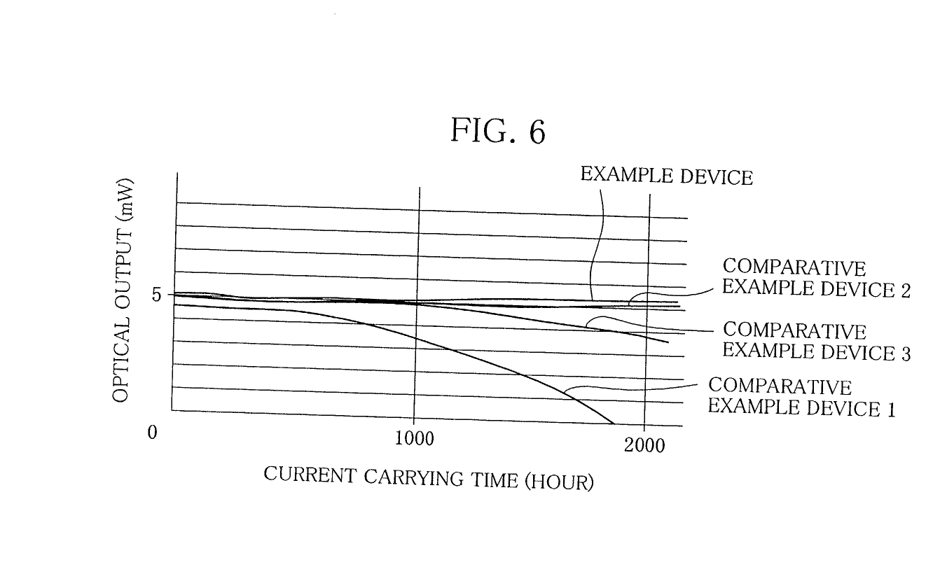

Next, with these laser devices the changes in the optical output power over time were measured under the constant current condition of an driving current of 10 mA and a temperature of 85° C. and the measuring conditions of a measuring current of 15 mA and a measuring temperature of 25° C. The result is shown in FIG. 6.

As apparent from FIG. 6, in the comparative example devices 1 and 3 in which each vicinity region to the light-emitting layer is not a low concentration doped region, the optical output power is decreased within 2000 hours for the driving time. However, in the example device of the present invention and the comparative example device 2 in which each vicinity region to the light-emitting layer is a low concentration doped region, even if the driving time exceeds 2000 hours, the reduction in optical output power is not recognized.

As explained above, the laser device of the present invention has a difference between the impurity doping concentrations in the vicinity region to the light-emitting layer and the remote region from the light-emitting layer, and, at the same time, sets so that the energy gap difference between the semiconductor layers forming the vicinity region is smaller than the energy gap difference between the semiconductor layers forming the remote region. Thus, according to the present invention, the deterioration of characteristics of optical output power does not occur, and the reduction in the driving voltage can be realized. Accordingly, the laser device of the present invention has a large industrial value as a high-efficient surface emitting semiconductor laser.

What is claimed is:

1. A surface emitting semiconductor laser device comprising:
a layered structure in which a light-emitting layer is disposed between a pair of reflector layered structures formed by hetero junction of a plurality of semiconductor materials, said layered structure being formed on a substrate and an impurity being doped into said reflector layered structure;
wherein in said reflector layered structure the doping concentration of said impurity into a region positioned in the vicinity of said light-emitting layer is relatively smaller than the doping concentration of said impurity into other regions; and at the same time, in said reflector layered structure said region positioned in the vicinity of said light-emitting layer has a relatively smaller energy gap difference between the semiconductor materials forming said region than the energy gap difference between the semiconductor materials forming said other regions.

2. The surface emitting semiconductor laser device according to claim 1, wherein said light-emitting layer is made of a GaAs compound semiconductor and emits a laser beam with a lasing wavelength band of 850 nm.

3. The surface emitting semiconductor laser device according to claim 1, wherein said light-emitting layer is made of a GaInNAs compound semiconductor and emits a laser beam with a lasing wavelength band of 1300 nm.

4. The surface emitting semiconductor laser device according to any one of claims 1 to 3, wherein said semiconductor material forming said reflector layered structure is AlGaAs.

5. The surface emitting semiconductor laser device according to any one of claims 1 to 3, wherein said semiconductor material forming said reflector layered structure is GaInAsP.
